(19) United States
(12) Patent Application Publication
(10) Pub. No.: US 2026/0123477 A1
(43) Pub. Date: Apr. 30, 2026

(54) THROUGH-SUBSTRATE-VIA LANDING PAD HAVING A MESH STRUCTURE

(71) Applicant: Taiwan Semiconductor Manufacturing Company, Ltd., Hsin-Chu (TW)

(72) Inventors: Mao-Nan Wang, Kaohsiung City (TW); Chih Hsin Yang, Hsinchu County (TW); Yu-Bey Wu, Hsinchu City (TW); Yang-Hsin Shih, Hsinchu City (TW); Liang-Wei Wang, Hsinchu City (TW); Kuan-Hsun Wang, Hsinchu City (TW); Yun-Sheng Li, Hsinchu (TW); Chih-Chieh Chang, Hsinchu (TW)

(21) Appl. No.: 19/030,094

(22) Filed: Jan. 17, 2025

Related U.S. Application Data
(60) Provisional application No. 63/712,733, filed on Oct. 28, 2024.

(51) Int. Cl. H01L 23/498; H01L 21/768

(52) U.S. Cl. CPC H10W 70/635; H10W 20/057; H10W 70/65

(57) ABSTRACT

A first interconnect structure is formed over a first side of a substrate. The first interconnect structure includes a plurality of first interconnect layers embedded in a first dielectric structure. One of the first interconnect layers includes a landing pad that has a mesh structure. A second interconnect structure is formed over a second side of the substrate opposite the first side. The second interconnect structure includes a plurality of second interconnect layers embedded in a second dielectric structure. A recess is formed that extends through the second dielectric structure and the substrate and partially through the first dielectric structure. The recess exposes at least a portion of the landing pad. A through-substrate-via (TSV) is formed by filling the recess with one or more conductive materials.

### PRIORITY DATA

The present application is a utility U.S. patent application of provisional U.S. Patent Application No. 63/712,733, filed on Oct. 28, 2024, entitled “MESH STRUCTURE FOR THROUGH-SUBSTRATE-VIA LANDING”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

However, as semiconductor fabrication progresses to more advanced technology nodes, additional fabrication challenges may arise. For example, the current implementation of landing pads for through-substrate-vias (TSVs) may lead to excessive wafer warpage and/or stress, which in turn could cause performance degradations or even failures. Therefore, better TSV landing pads are needed.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A is a diagrammatic perspective view of a semiconductor device.

FIG. 1B is a diagrammatic top view of a semiconductor device.

FIG. 1C is a diagrammatic cross-sectional side view of a semiconductor device.

FIGS. 2-12 illustrate various cross-sectional side views of a portion of an IC device according to embodiments of the present disclosure.

FIGS. 13A and 14A illustrate various planar top views of a portion of an IC device according to embodiments of the present disclosure.

FIGS. 13B and 14B illustrate various cross-sectional side views of a portion of an IC device according to embodiments of the present disclosure.

FIGS. 15A-15F illustrate various planar top views of a portion of an IC device according to embodiments of the present disclosure.

FIG. 16 illustrates an original IC design layout and a revised IC design layout of a portion of an IC device according to embodiments of the present disclosure.

FIG. 17 illustrates a flowchart of a method of fabricating an IC device according to embodiments of the present disclosure.

FIG. 18 illustrates an integrated circuit fabrication system according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to an improved design of the landing pad for a through-substrate-via (TSV), and more particularly, to a TSV landing pad having a mesh structure, which helps to reduce stress and/or wafer warpage. In more detail, TSVs are used to provide electrical connectivity in integrated circuit (IC) packaging. Conductive landing pads are implemented to provide a landing space for the TSVs, and the conductive landing pads may provide electrical connections, as well as mechanical support, for the TSVs. For reasons of convenience, current TSV landing pads are typically implemented as a solid block of metal. Unfortunately, such a solid-block design for the TSV landing pads may have a greater-than-optimal metal pattern density, which could lead to wafer warpage and or excessive stress. Furthermore, TSV landing pads with the solid-block design may have excessive thermal expansion and/or contraction, which could further exacerbate the wafer warpage and/or stress.

To address the issues discussed above, the present disclosure implements the TSV landing pads as mesh structures. For example, rather than implementing a TSV landing pad as a solid metal block, the present disclosure may implement the TSV as a plurality of metal strip segments that are separated from one another in certain cross-sectional side views and/or planar top views in some embodiments. The mesh structure of the TSV landing pads herein may also entail various geometric designs and/or shapes in the planar top view, such that the metal pattern density corresponding to the TSV landing pad is not 100% (which would have been the case for a solid-block design for the TSV landing pad), but rather in a predefined range (e.g., 20% to 80%) that is less than 100%. Such a mesh structure design for the TSV landing pad may allow for reduced stress and/or better tolerances with respect to thermal expansion and/or contraction, which may then lead to reduced wafer warpage and/or stress. Consequently, IC device performance and/or yield may be improved.

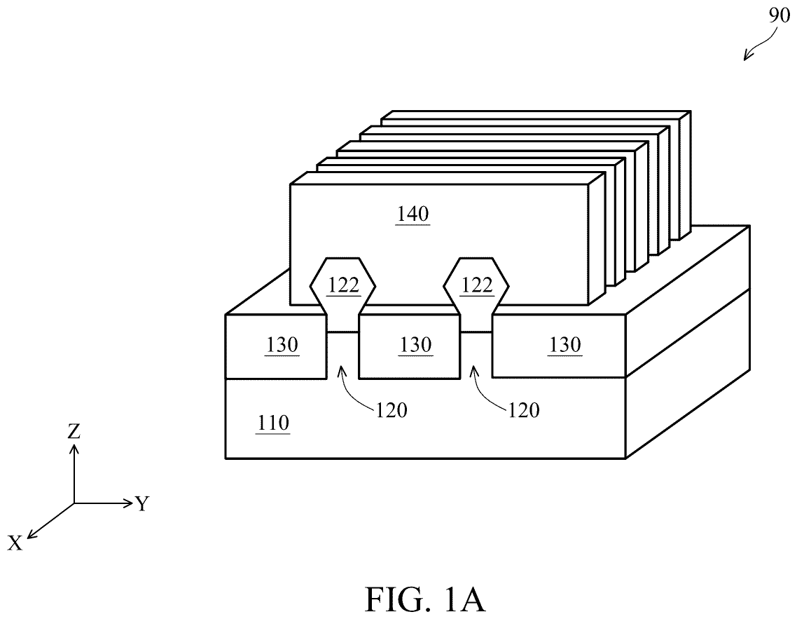

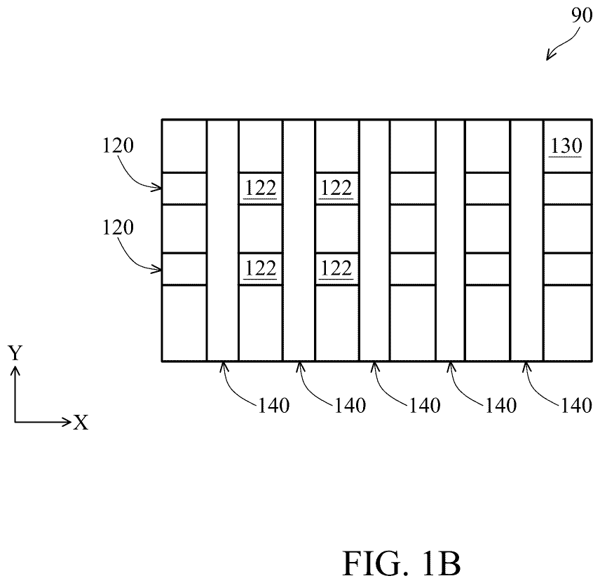

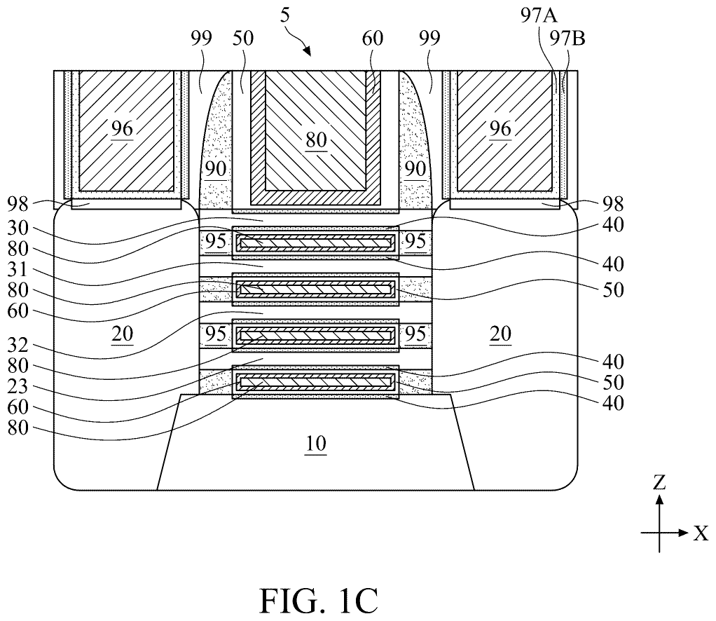

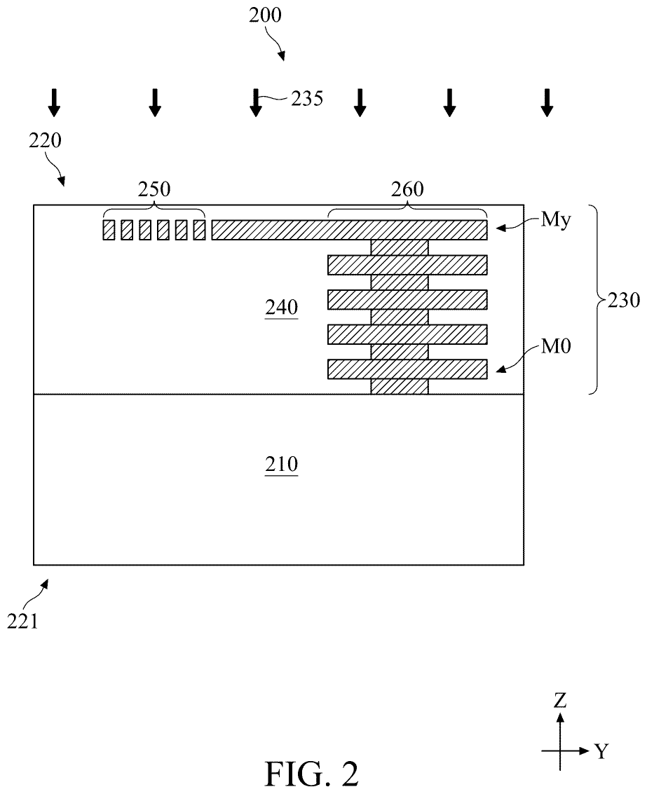

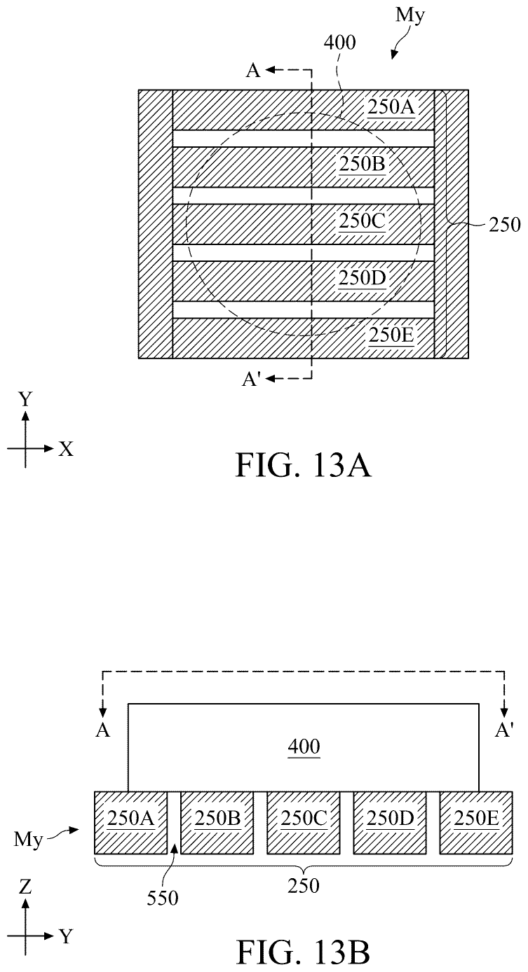

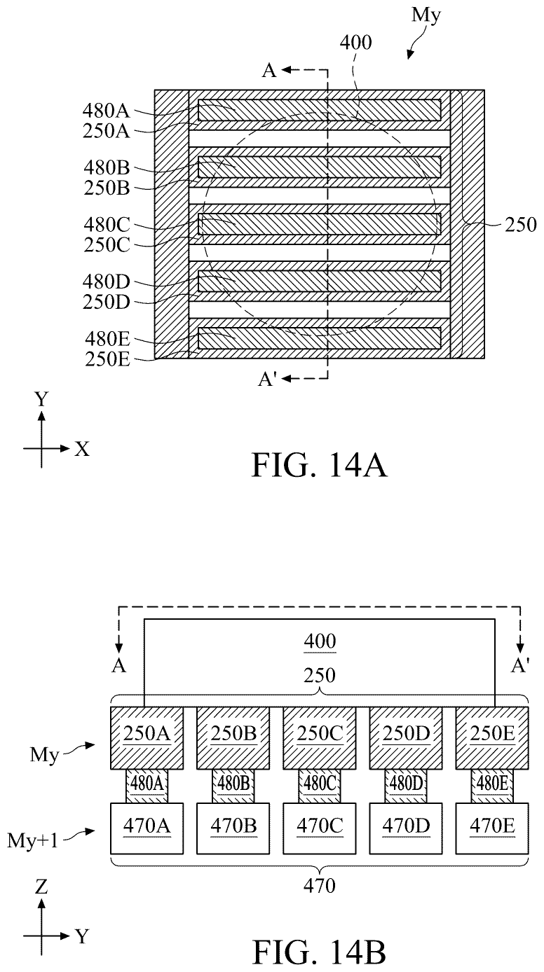

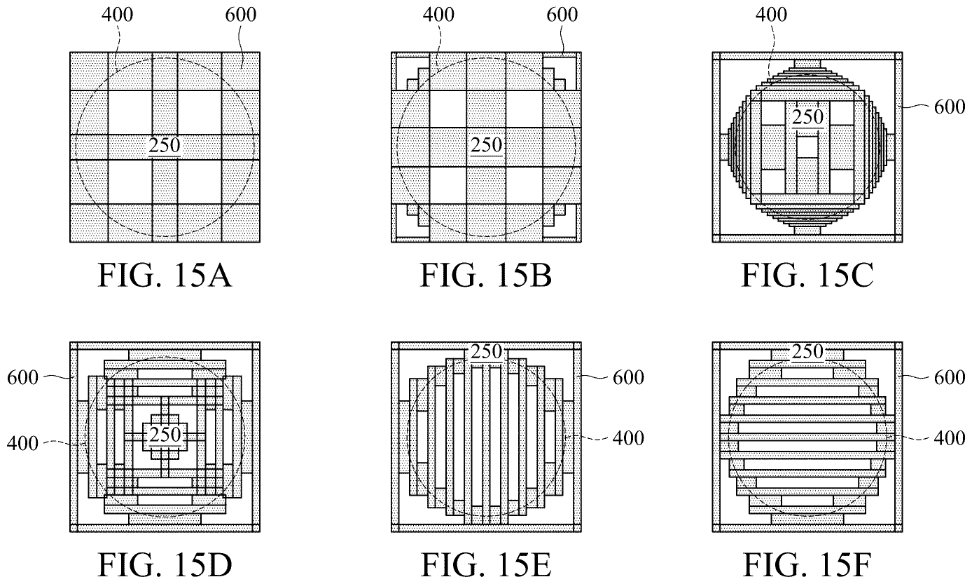

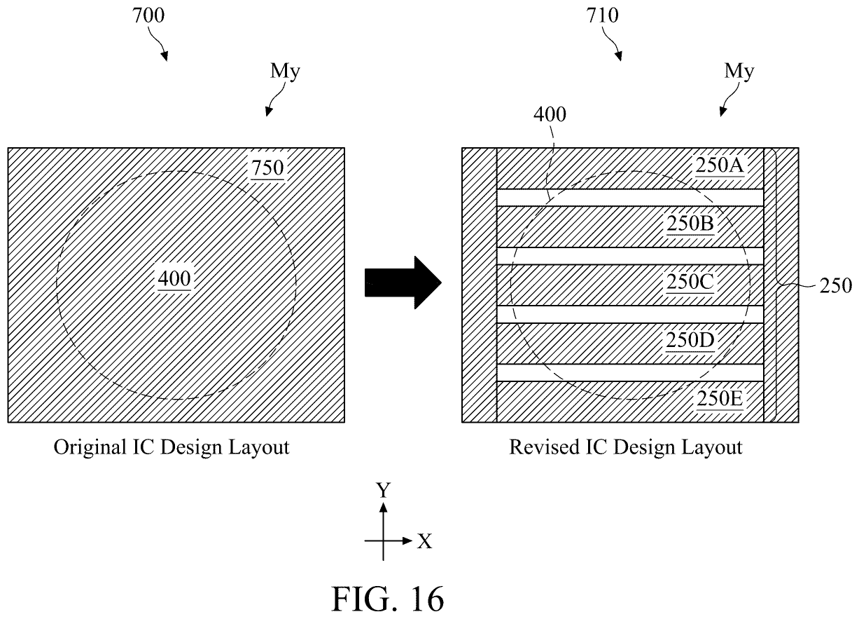

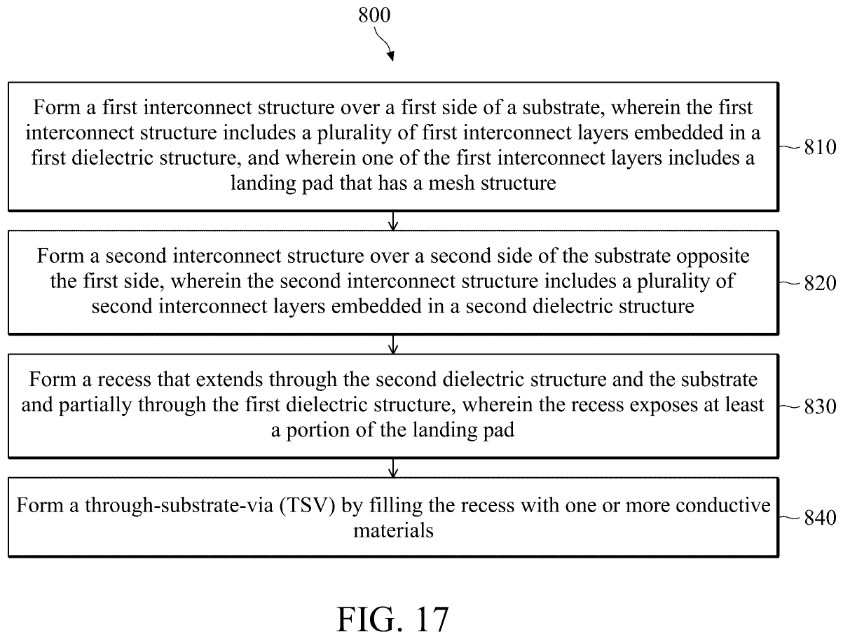

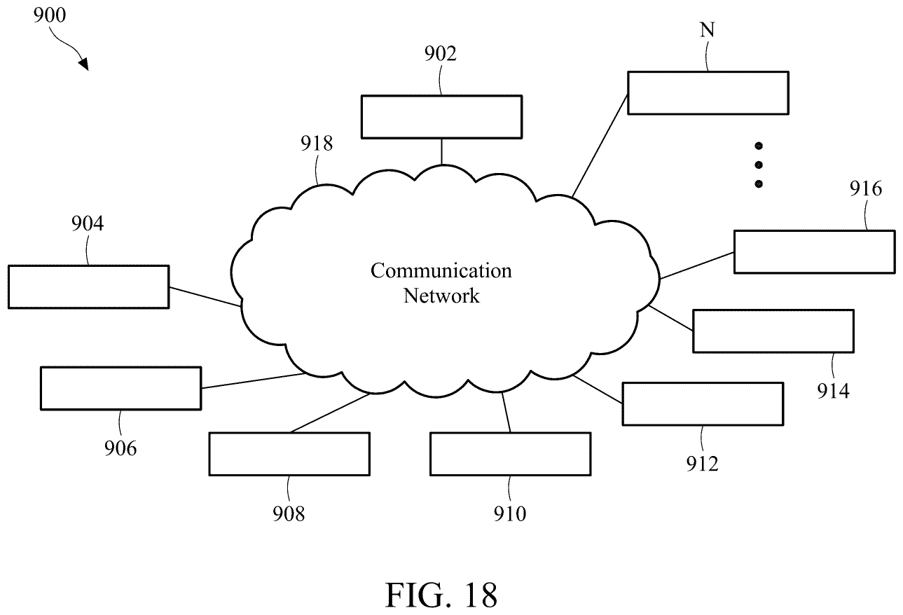

The various aspects of the present disclosure are now discussed in greater detail with reference to FIGS. 1-18. In more detail, FIGS. 1A-1C will describe the basic structures of example transistor devices that could be implemented in an IC device. FIGS. 2-12 illustrate various cross-sectional side views of a portion of an IC device at different stages of fabrication according to embodiments of the present disclosure. FIGS. 13A-14A illustrate various planar top views of a TSV landing pad, and FIGS. 13B-14B illustrate various cross-sectional side views of the TSV landing pad according to embodiments of the present disclosure. FIGS. 15A-15F illustrate IC design layouts of the mesh structure of the TSV landing pad according to various embodiments of the present disclosure. FIG. 16 illustrates a process of revising an original IC design layout to generate a revised IC design layout of corresponding to a TSV landing pad according to embodiments of the present disclosure. FIG. 17 illustrates a flowchart of a method of fabricating an IC device according to embodiments of the present disclosure. FIG. 18 illustrates an integrated circuit fabrication system according to various aspects of the present disclosure.

Referring now to FIGS. 1A and 1B, a three-dimensional perspective view and a top view of a portion of an Integrated Circuit (IC) device 90 are illustrated, respectively. The IC device 90 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells.

In the example shown in FIGS. 1A and 1B, the IC device 90 is a three-dimensional fin-shaped FET (FinFET) device. In that regard, a FinFET device is a fin-like field-effect transistor device, which has been gaining popularity recently in the semiconductor industry, since it offers several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices for a portion of, or the entire IC chip.

Referring to FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions, including nano-structures 170, are formed on the substrate 110. The active regions are elongated fin-like structures that protrude upwardly out of the substrate 110. The protrusion structure 120 may be interchangeably referred to as fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fin structures 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a diagrammatic cross-sectional side view of a portion of an IC device 5 fabricated according to embodiments of the present disclosure, where the IC device 5 is a gate-all-around (GAA) device and may be referred to as a GAA device 5 hereinafter. It is understood that the GAA device 5 may be an NFET in some embodiments, or it may be a PFET in other embodiments.

Referring to FIG. 1C, the cross-sectional view of the GAA device 5 is taken along an X-Z plane, where the X-direction (same X-direction as in FIG. 1A) is the horizontal direction, and the Z-direction (same Z-direction as in FIG. 1A) is the vertical direction. The GAA device 5 includes a fin structure 10, which may be similar to the fin structure 120 discussed above. In some embodiments, the fin structure 10 includes silicon. The GAA device 5 includes source/drain features 20, which may be similar to the source/drain features 122 discussed above. In embodiments where the GAA device 5 is an NFET, the source/drain features 20 include silicon phosphorous (SiP). In embodiments where the GAA device 5 is a PFET, the source/drain features 20 include silicon germanium (SiGe).

The GAA device 5 includes a plurality of channels, for example channels 30-33 as shown in FIG. 1C. The channels 30-33 each include a semiconductive material, for example silicon or a silicon compound. The channels 30-33 are nanostructures (e.g., having sizes that are in a range of a few nanometers) and may also each have an elongated shape and extend in the X-direction. In some embodiments, the channels 30-33 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 30-33 may be different from each other. For example, a length of the channel 30 may be less than a length of the channel 31, which may be less than a length of the channel 32, which may be less than a length of the channel 33. In some embodiments, each of the channels 30-33 may not have uniform thicknesses.

In some embodiments, a spacing (e.g., measured in the Z-direction) between the channels 30-33 (each channel from adjacent channels) is in a range between about nanometers (nm) and about 12 nm. In some embodiments, a thickness (e.g., measured in the Z-direction) of each of the channels 30-33 is in a range between about 5 nm and about nm. In some embodiments, a width (e.g., measured in the Y-direction of FIG. 1A) of each of the channels 30-33 is in a range between about 15 nm and about 150 nm. A plurality of interfacial layers (ILs) 40 may also be formed on the upper and lower surfaces of the channels 30-33.

The GAA device 5 also includes gate structures that are disposed over and in between the channels 30-33. The gate structures may include gate dielectric layers 50. In some embodiments, the gate dielectric layers 50 include a high-k gate dielectric. The gate structures further include one or more work function metal layers 60. In embodiments where the GAA device 5 is an NFET, the one or more work function metal layers 60 include N-type work function metal layers, such as TiAlC. In embodiments where the GAA device 5 is a PFET, the one or more work function metal layers 60 include P-type work function metal layers, such as TiN.

The gate structures also include fill metals 80. In the portion of the gate structure formed over the channels 30-33, the fill metal 80 are formed over the one or more work function metal layers 60. The one or more work function metal layers 60 have a U-shape and wrap around the fill metal 80, and the gate dielectric layer 50 also has a U-shape and wrap around the one or more work function metal layers 60. In portions of the gate structures formed between the channels 30-33, the fill metal 80 is circumferentially surrounded (in the cross-sectional view) by the one or more work function metal layers 60, which is then circumferentially surrounded by the gate dielectric layer 50. It is understood that the gate structures may also include a glue layer that is formed between the one or more work function metal layers 60 and the fill metal 80 to increase adhesion. However, for reasons of simplicity, such a glue layer is not specifically illustrated herein.

The GAA device 5 also includes gate spacers 90 and inner spacers 95 that are disposed on sidewalls of the gate dielectric layer 50. The inner spacers 95 are also disposed between the channels 30-33. The gate spacers and the inner spacers 95 may include a dielectric material, for example a low-k material such as SiOCN, SiON, SiN, or SiOC.

The GAA device 5 further includes source/drain contacts 96 that are formed over the source/drain features 20. The source/drain contacts 96 may include a conductive material such as cobalt, copper, aluminum, tungsten, or combinations thereof. The source/drain contacts 96 are surrounded by barrier layers, for example barrier layers 97A and 97B, which help prevent or reduce diffusion of materials from and into the source/drain contacts 96. In some embodiments, the barrier layer 97A includes TiN, and the barrier layer 97B includes SiN. A silicide layer 98 may also be formed between the source/drain features 20 and the source/drain contacts 96, so as to reduce the source/drain contact resistance. The silicide layer 98 may contain a metal silicide material, such as cobalt silicide in some embodiments.

The GAA device 5 further includes an interlayer dielectric (ILD) 99. The ILD 99 provides electrical isolation between the various components of the GAA device 5, for example between the gate structures and the source/drain contacts 96.

GAA devices may also offer advantages such as better chip area efficiency, improved carrier mobility, etc. As such, advanced IC chips may be implemented using the GAA devices as well. However, it is understood that the present disclosure is not limited to any particular number of devices or device regions, or to any particular device configurations, unless otherwise claimed. For example, although FinFET devices or GAA devices have been described as potential transistors that could be used to implement the IC chip or a portion thereof, the concepts of the present disclosure discussed in more detail below may also apply to IC chips implemented using planar FET devices as well.

FIGS. 2-12 are a series of cross-sectional side views illustrating a fabrication process flow for manufacturing a TSV landing pad with a mesh structure according to embodiments of the present disclosure. The cross-sectional side views are taken along a Y-Z plane, which is defined by a Y-direction horizontally and a Z-direction vertically. Referring to FIG. 2, an IC device 200 illustrated herein includes a portion of a wafer. In the illustrated embodiment, the IC device 200 includes a substrate 210, which may be an embodiment of the substrate 110 discussed above. For example, the substrate 210 may comprise an elementary semiconductor (e.g., silicon or germanium), a compound semiconductor (e.g., silicon carbide, gallium arsenic, gallium phosphide, indium phosphide, indium arsenide, or indium antimonide), or an alloy semiconductor (e.g., SiGe, GaAsP, AlInAs, AlGaAs, GaInAs, GaInP, or GaInAsP). The substrate 210 may also be a single-layer material having a uniform composition in some embodiments or may include multiple material layers having similar or different compositions suitable for IC device manufacturing (e.g., a silicon-on-insulator (SOI) substrate having a semiconductor silicon layer formed on a silicon oxide layer). Transistors such as the FinFET devices or the GAA devices discussed above with reference to FIGS. 1A-1C may be formed in or on the substrate 210 to form various types of electrical circuitry. For reasons of simplicity, however, the circuitry is not specifically illustrated herein.

The substrate 210 has two opposite sides: a side 220 (which may be referred to as a “front side”) and a side 221 (which may be referred to as a “back side”). An interconnect structure 230 is formed over the side 220 of the substrate 210 in an interconnect structure formation process 235. In that regard, the interconnect structure 230 may be a multi-layer interconnect (MLI) structure that includes a plurality of interconnect layers (e.g., M₀ through M_{y}), as well as a plurality of conductive vias that interconnect the various interconnect layers together. The interconnect layers may include a plurality of metal lines, which may be implemented as elongated conductive strips. The metal lines are configured to route electrical signals, and the metal lines from different interconnect layers are interconnected together by the conductive vias. As shown in FIG. 2, the metal lines and conductive vias are embedded in a dielectric material 240 of the interconnect structure 230, which provides electrical isolation for the metal lines and/or conductive vias as appropriate.

In various embodiments, the dielectric material 240 may also be formed of silicon oxide, silicon oxynitride, silicon nitride, silicon carbide, or a low-k dielectric material having a dielectric constant lower than that of silicon oxide (e.g., less about 3.9). As non-limiting examples, the low-k dielectric material may include Black Diamond (a registered trademark of Applied Materials), a carbon-containing low-k dielectric material, Hydrogen SilsesQuioxane (HSQ), MethylSilsesQuioxane (MSQ), or the like. These dielectric materials may be formed via one or more deposition processes of the interconnect structure formation process 235. In various embodiments, the metal lines and the conductive vias may be formed using damascene processes (e.g., a dual damascene process) as a part of the interconnect structure formation process 235. In various embodiments, the metal lines and/or the conductive vias may include copper on diffusion barrier layers. The diffusion barrier layers may be formed of titanium, titanium nitride, tantalum, tantalum nitride, or the like.

According to various aspects of the present disclosure, a subset of the metal lines of the topmost (e.g., farthest from the substrate 210) interconnect layer M_{y} may be specifically configured to implement a TSV landing pad 250 that has a mesh structure. In the cross-sectional side view of FIG. 2, such a mesh structure manifests itself as being comprised of a plurality of metal line segments that are separated from one another in the Y-direction horizontally, where the gaps between the metal lines are filled by portions of the dielectric material 240. Such a mesh structure of the TSV landing pad 250 may offer benefits with respect to wafer warpage and/or stress. For example, the mesh structure allows the stress associated with the TSV landing pad 250 to be more evenly distributed and/or reduced, which could lead to a reduction in wafer warpage. Furthermore, since the TSV landing pad 250 is not just a single piece of metal block, there is more room for each conductive member of the TSV landing pad 250 to contract and/or expand in response to different thermal conditions, which also reduces the wafer warpage. In some embodiments, the mesh structure is configured so that the metal pattern density of the TSV landing pad 250 is in a range between about 20% and about 80%. Such a range is specifically configured such that the TSV landing pad 250 can achieve the potential benefits pertaining to the stress reduction and more flexible thermal contraction/expansion, while still being able to handle its intended functionality of providing electrical connectivity and mechanical support for the TSV (to be formed in a later process).

Note that the TSV landing pad 250 may be located in a region of the interconnect structure 230 that is away from a “main region” 260 of the interconnect structure 230, where a substantial majority (if not all) of the metal lines and conductive vias may be located for electrical routing purposes. In other words, between the TSV landing pad 250 and the substrate 210, there may not be any metal lines or conductive vias of the interconnect structure 230. That is, a portion of the dielectric material 240 (but not any conductive elements of the interconnect layers of the interconnect structure 230) is located directly below the TSV landing pad 250. This is so that a TSV (formed in a later fabrication stage) may extend through the portion of the dielectric material 240 between the TSV landing pad 250 and the substrate 210 without accidentally electrically shorting into another conductive element.

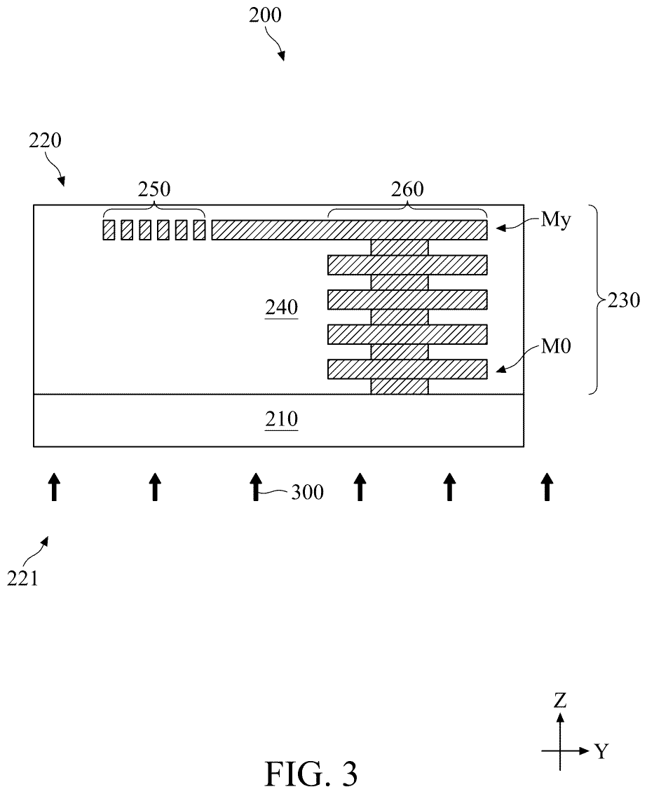

Referring now to FIG. 3, a substrate thinning process 300 is applied to the IC device 200 from the side 221. In some embodiments, the substrate thinning process 300 may include a mechanical grinding process and a chemical thinning process. For example, a substantial amount of substrate material may be first removed from the substrate 210 during the mechanical grinding process. Afterwards, the chemical thinning process may apply an etching chemical to the side 221 of the substrate 210 to further reduce a thickness of the substrate 210. As a result of the substrate thinning process 300, the thickness of the substrate 210 in the vertical Z-direction is substantially reduced. For example, the substrate 210 may have a thickness on the order of a few microns (or tens of microns) at the completion of the substrate thinning process 300 in some embodiments.

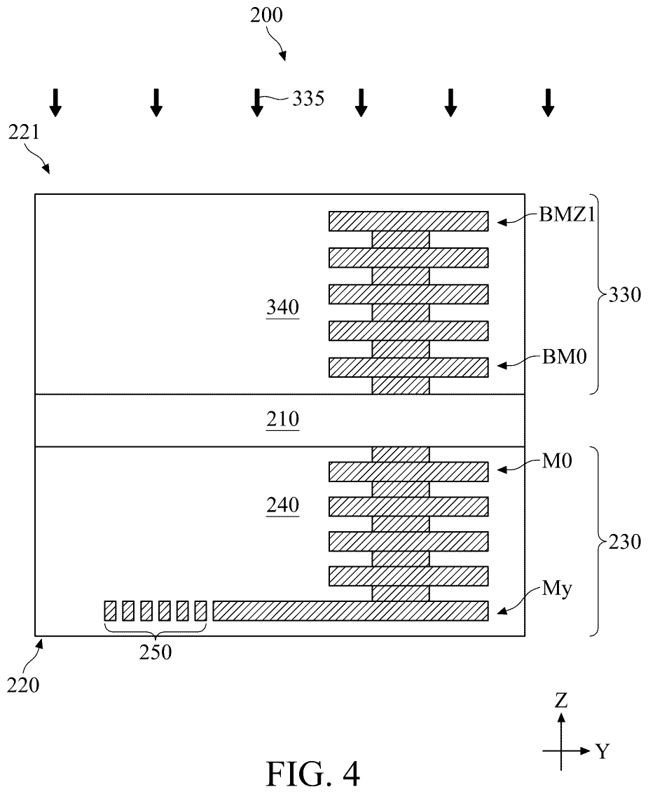

Referring now to FIG. 4, the illustrated IC device 200 is flipped upside down vertically in the Z-direction, such that the sides 220 and 221 are switched. In other words, the interconnect structure 230 is now disposed below the substrate 210 in FIG. 4. Note that the vertical flipping of the IC device 200 may also be done before the substrate thinning process 300 is performed. In any case, an interconnect structure 330 is formed over the side 221 of the substrate 210 via an interconnect structure formation process 335. Similar to the interconnect structure 230, the interconnect structure 330 may also be a MLI structure that includes a plurality of interconnect layers (e.g., BM₀ through BM_{z1}), as well as a plurality of conductive vias for interconnecting the various interconnect layers together. The interconnect layers and the conductive vias are also embedded in a dielectric material 340, which may have a substantially similar material composition as the dielectric material 240 discussed above.

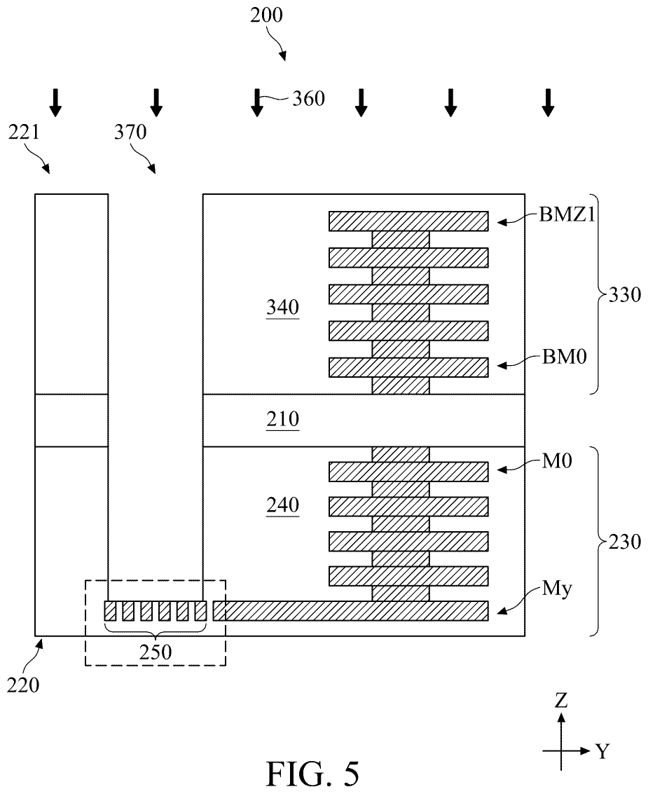

Referring now to FIG. 5, one or more etching processes 360 may be performed to etch a recess 370 that extends vertically through the interconnect structure 330, the substrate 210, and partially through the interconnect structure 230 in the IC device 200. For example, the one or more etching processes 360 may include a dry etching process in some embodiments or a wet etching process in other embodiments. The one or more etching processes 360 may be performed until the TSV landing pad 250 is reached. In other words, the one or more etching processes 360 may be configured to have an etching selectivity between the materials of the interconnect layer M_{y} and the rest of the IC device 200, including the dielectric materials 240/340 and the substrate 210. For example, the one or more etching processes 360 may be configured to etch away the dielectric materials 340/240 and the material of the substrate 210 at a substantially faster rate than the materials (e.g., one or more metal materials) of the interconnect layer M_{y}, and it may stop once it is detected that the interconnect layer M_{y} are reached. In this manner, the interconnect layer M_{y} may serve as an etching-stop layer. At the completion of the one or more etching processes 360, the surfaces of the interconnect layer M_{y} are exposed to the side 221 by the recess 370. The recess 370 may also be referred to as a TSV trench, since it will be filled by a TSV in a subsequent process.

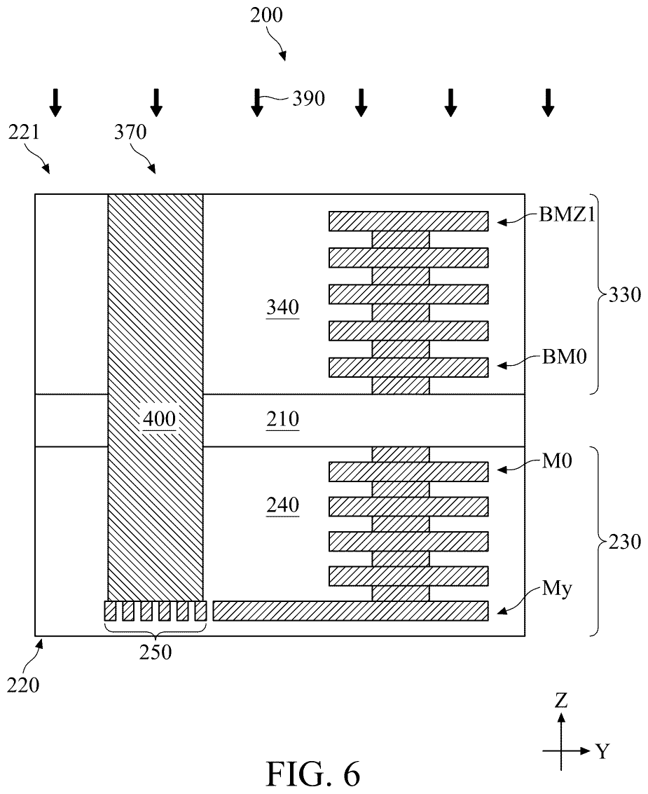

Referring now to FIG. 6, a TSV formation process 390 is performed to form a TSV 400 in the recess 370. For example, the TSV formation process 390 may include one or more deposition processes, such as chemical vapor deposition (CVD), physical vapor deposition (PVD), atomic layer deposition (ALD), etc. The deposition processes deposit one or more conductive materials in the recess 370. For example, the deposition processes may first deposit a barrier layer to partially fill the recess 370, where the barrier layer may be deposited to be in physical contact with the TSV landing pad 250. Thereafter, an electroplating process may be performed as a part of the TSV formation process 390 to fully fill the recess 370 with a metal material, such as copper. The metal material may be formed on the barrier layer. At this stage of fabrication, the TSV 400 extends through the interconnect structure 330 (e.g., vertically through the dielectric material 340), through the substrate 210, and partially through the interconnect structure 230 (e.g., vertically through the dielectric material 240).

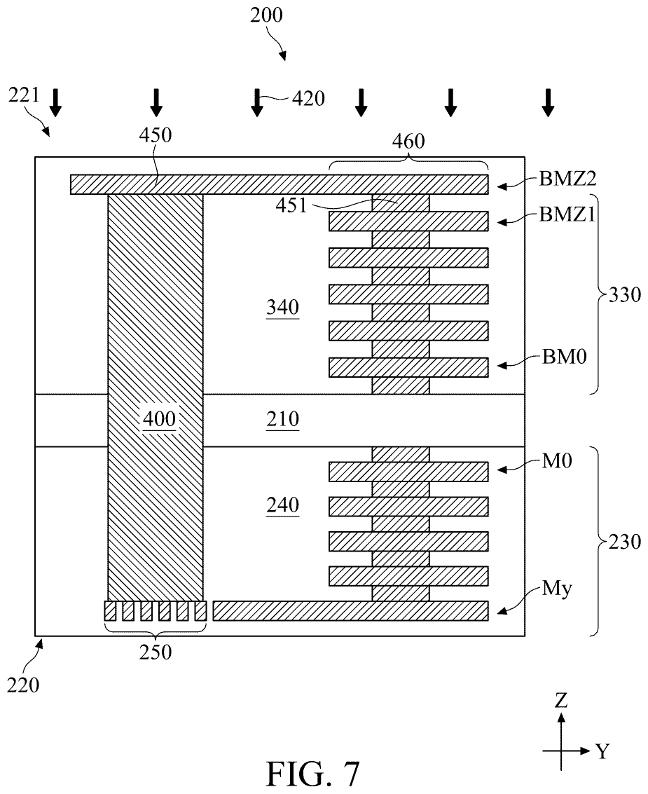

Referring now to FIG. 7, an interconnect layer formation process 420 is performed to form an interconnect layer BM_{Z2} as topmost one of the interconnect layers of the interconnect structure 330. The interconnect layer formation process 420 may include a deposition process to deposit additional amounts of the dielectric material 340 over the TSV 400 and over the rest of the interconnect structure 330 (e.g., over the BM_{Z1} layer). Thereafter, a dual damascene process may be performed to etch trenches in the dielectric material 340 and to fill the etched trenches with a conductive material, thereby forming a conductive pad 450 and a conductive via 451 that interconnects the conductive pad 450 with the BM_{Z1} layer of the interconnect structure 330. As shown in the cross-sectional side view of FIG. 7, a bottom surface of the conductive pad 450 extends to a top surface of the TSV 400. In other words, the conductive pad 450 is in physical contact (and electrical contact as well) with the TSV 400. Since the bottom surface of the TSV 400 extends to the top surfaces of the TSV landing pad 250—e.g., the TSV 400 is in physical and electrical contact with the TSV landing pad 250—it may be said that the TSV 400 electrically couples the conductive pad 450 and the TSV landing pad 250 together, which also means that electrical connectivity between the interconnect structure 230 and the interconnect structure 330 may be established as well.

Note that since the conductive pad 450 is in physical contact with the TSV 400, it may be viewed as another landing pad for the TSV 400, and it may be interchangeably referred to as such. In the embodiment shown in FIG. 7, the conductive pad 450 has a solid block configuration: it may be a single piece of metal that extends to a “main region” 460 of the interconnect structure 330, where a substantial majority (if not all) of the metal lines and conductive vias of the interconnect structure 330 are located for electrical routing purposes. However, the conductive pad 450 may assume a mesh structure similar to the TSV landing pad 250 in other embodiments as well.

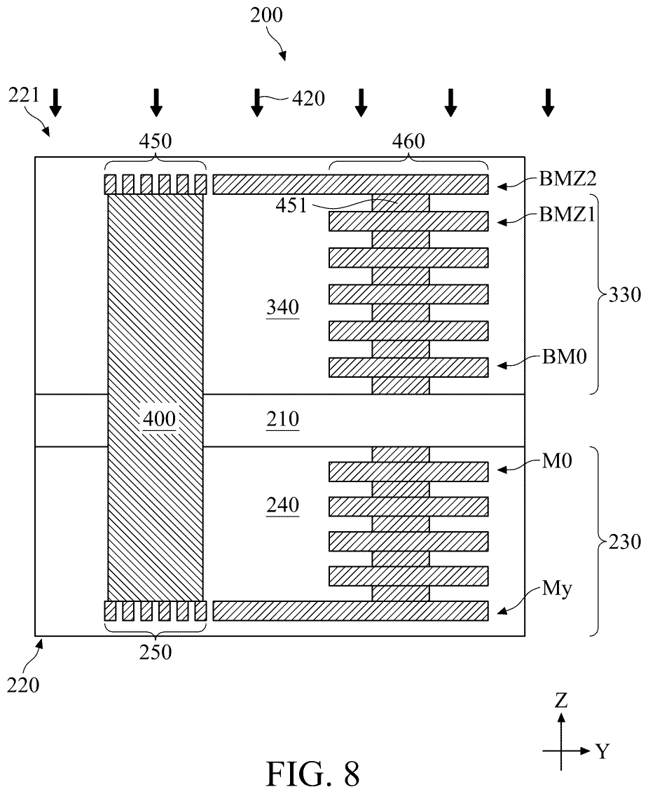

To illustrate, in an alternative embodiment shown in FIG. 8, the conductive pad 450 may be implemented similar to the TSV landing pad 250. For example, similar to the TSV landing pad 250, the conductive pad 450 is no longer a single solid metal block, but rather is made up of a plurality of conductive strips (e.g., each one being a different metal line segment of the interconnect layer BM_{Z2}), which are separated from one another in the Y-direction by a plurality of gaps (with the dielectric material 340 filling these gaps).

It is also understood that the TSV landing pad 250 need not be formed in the bottommost one of the interconnect layers of the interconnect structure 230, and/or that the conductive pad 450 need not be formed in the topmost one of the interconnect layers of the interconnect structure 330. Additional conductive pads—which may also have mesh structures—may be implemented above the conductive pad 450 and/or below the TSV landing pad 250 in other embodiments.

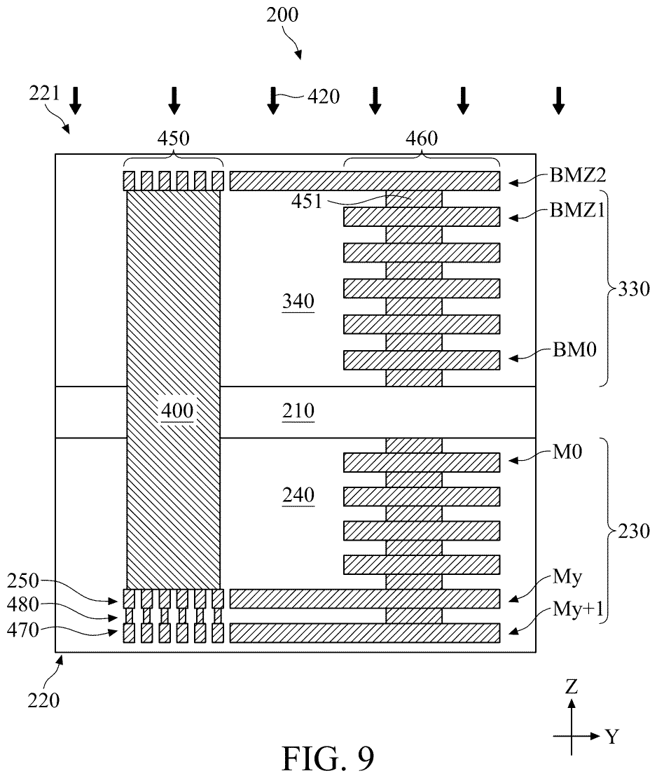

FIG. 9 illustrates such an alternative embodiment of the present disclosure. In the embodiment of FIG. 9, the interconnect structure 230 may further include a M_{y+1} interconnect layer that is located “below” the M_{y} interconnect layer, such that it is located farther away from the substrate 210 than the rest of the interconnect layers of the interconnect structure 230. The M_{y+1} interconnect layer includes a conductive pad 470 that also has a mesh structure. For example, the mesh structure of the conductive pad 470 may be similar to the mesh structure of the TSV landing pad 250, in that it includes a plurality of conductive strips separated from one another in the Y-direction. The conductive pad 470 is electrically coupled to the TSV landing pad 250 through a plurality of conductive vias 480. For example, each conductive strip (e.g., metal line) of the conductive pad 470 is connected to a respective one of the conductive strips of the TSV landing pad 250 through a different conductive via.

It is understood that the M_{y+1} interconnect layer (including the conductive pad 470) is formed before the formation of the TSV 400 (e.g., before the formation of the recess 370). Beneficially, the conductive pad 470 may serve as an additional etching-stop layer. For example, even if the etching of the recess 370 is too aggressive, such that it extends beyond the TSV landing pad 250 of the M_{y} interconnect layer, it can still stop at the conductive pad 470 of the M_{y+1} interconnect layer.

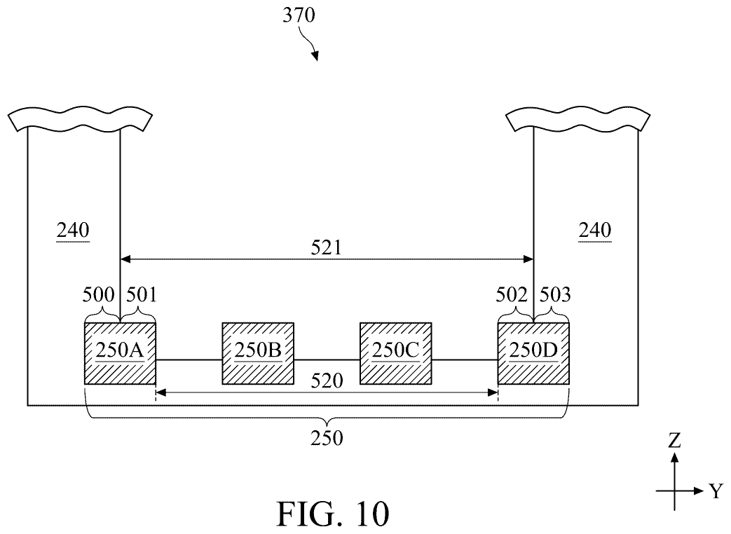

Regardless of whether the embodiment of FIG. 9 or the embodiment of FIG. 10 is implemented, additional fabrication processes may be performed to complete the fabrication of the IC device 200. For example, the IC device 200 may be bonded or otherwise coupled to another IC die through the side 220. In some embodiments, the other IC die may be a substantially identical die as the IC die of the IC device 200. In other embodiments, the IC die may have different functionalities than the IC device 200. The side 221 of the IC device 200 may also be bonded to a carrier, or conductive bumps may be formed to further provide electrical connectivity between the IC device 200 and other external devices.

FIGS. 10-12 are magnified cross-sectional side views corresponding to a portion of the IC device 200 to illustrate different stages of the TSV formation. In more detail, the magnified view corresponds to the portion of the IC device covered by the dashed box in FIG. 5, which includes a bottom portion of the recess 370 and the TSV landing pad 250. Referring now to FIG. 10, the stage of fabrication is the same stage as shown in FIG. 5, that is, after the recess 370 has been etched, but before the TSV 400 has been formed to fill the recess 370. For reasons of simplicity, the TSV landing pad 250 shown in FIG. 10 includes four distinct conductive segments 250A, 250B, 250C, and 250D as a part of the mesh structure. However, it is understood that the TSV landing pad 250 may include more or less than four of such conductive segments 250A-250D in other embodiments.

According to one aspect of the present disclosure, the etching of the recess 370 is specifically configured such that the upper surfaces of some of the conductive segments are partially, but not completely exposed. For example, the conductive segment 250A has an upper surface that is comprised of a portion 500 and a portion 501, where the portion 501 is exposed by the recess 370, but the portion 500 is not exposed by the recess 370, but is covered by a portion of the dielectric material 240 instead. Alternatively stated, the etching of the recess 370 is configured such that the upper right corner (i.e., the corner that is facing the toward the recess 370) is exposed, but the upper left corner (i.e., the corner that is facing away from the recess 370) is covered by the dielectric material 240. Similarly, the conductive segment 250D has a portion 502 of an upper surface that is exposed by the recess 370 and a portion 503 of the upper surface that is not exposed but is covered by a portion of the dielectric material 240 instead, which means that the upper left corner of the conductive segment 250D is exposed, but the upper right corner of the conductive segment 250D is covered by the dielectric material 240.

The configuration of the recess 370 discussed above also leads to differences in lateral dimensions of the recess 370 at different depth levels. For example, a bottom portion of the recess 370 has a lateral dimension 520 in the Y-direction, which is measured from the right edge of the conductive segment 250A to the left edge of the conductive segment 250D. Meanwhile, a portion of the recess 370 that is located above the conductive segments 250A-250D has a lateral dimension 521 in the Y-direction, which is measured between the two edges of the dielectric material 240. The lateral dimension 521 is greater than the lateral dimension 520, which is an inherent result of the fact that the conductive segments 250A and 250D each protrude laterally beyond the edges of the dielectric material 240 in a direction toward the center of the recess 370.

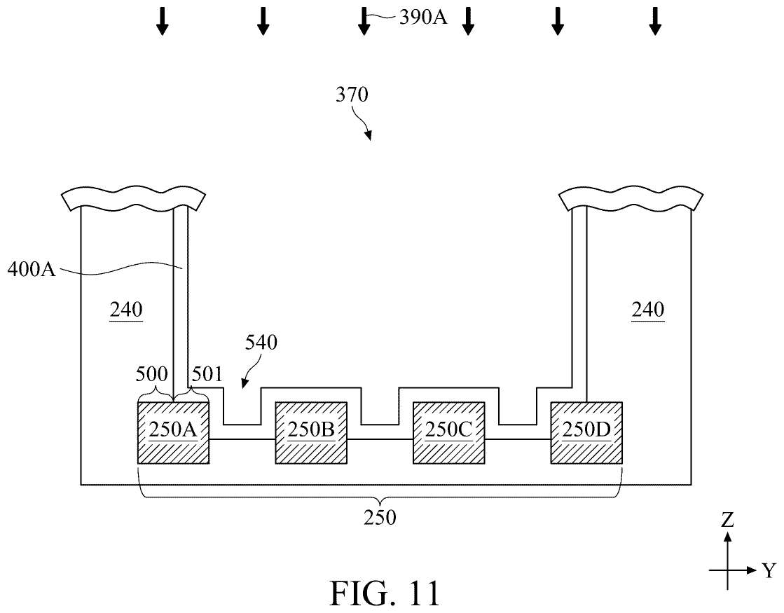

The configuration of the recess 370 discussed above confers certain benefits. For example, it reduces the likelihood of air bubbles or voids being trapped in the TSV 400, which is to be formed in a subsequent fabrication stage. In more detail, referring now to FIG. 11, a deposition process 390A (as a part of the TSV formation process 390) is performed to deposit a barrier layer 400A in the recess 370. The barrier layer 400A is formed on the portion 501 of the upper surface of the conductive segment 250A, as well as on the exposed right edge surface of the conductive segment 250A. The barrier layer 400A is also deposited on portions of the bottom surface of the dielectric material 240 that is disposed between the conductive segments 250A and 250B. Since a gap 540 laterally separating the conductive segments 250A and 250B is relatively wide, the barrier layer 400A can be deposited with good gap-filling performance, and the likelihood of air bubbles or voids being trapped underneath the barrier layer 400A is low.

In comparison, had the recess 370 not been configured in the manner discussed above, the sidewall of the dielectric material 240 (i.e., the edge defining the left edge of the recess 370) would have been disposed to either the left or the right of the conductive segment 250A. Suppose that such a sidewall of the dielectric material 240 is disposed to the right of the conductive segment 250A (meaning that the entire upper surface of the conductive segment 250A is covered by the dielectric material 240), then the resulting gap 540 between the sidewall of the dielectric material 240 and the left sidewall of the conductive segment 250B would have been smaller (i.e., narrower in the Y-direction). The smaller gap 540 could lead to gap-filling issues, which may cause air bubbles or voids to be trapped beneath or within the barrier layer 400A. Similarly, suppose that the sidewall of the dielectric material 240 is disposed to the left of the conductive segment 250A (meaning that the entire upper surface of the conductive segment 250A is exposed to the recess 370), then a resulting gap between the sidewall of the dielectric material 240 and the left sidewall of the conductive segment 250A could also be quite small (i.e., narrow in the Y-direction). Such a small gap 540 could also lead to gap-filling issues and cause air bubbles or voids to be trapped beneath or within the barrier layer 400A. The present disclosure avoids these potential issues by carefully configuring the recess 370 to expose a portion, but not all, of the upper surfaces of the conductive segments 250A and 250D, which improves gap filling performance of the barrier layer 400A and reduces the likelihood of air bubbles or voids being trapped by the barrier layer 400A. Consequently, device performance may be improved.

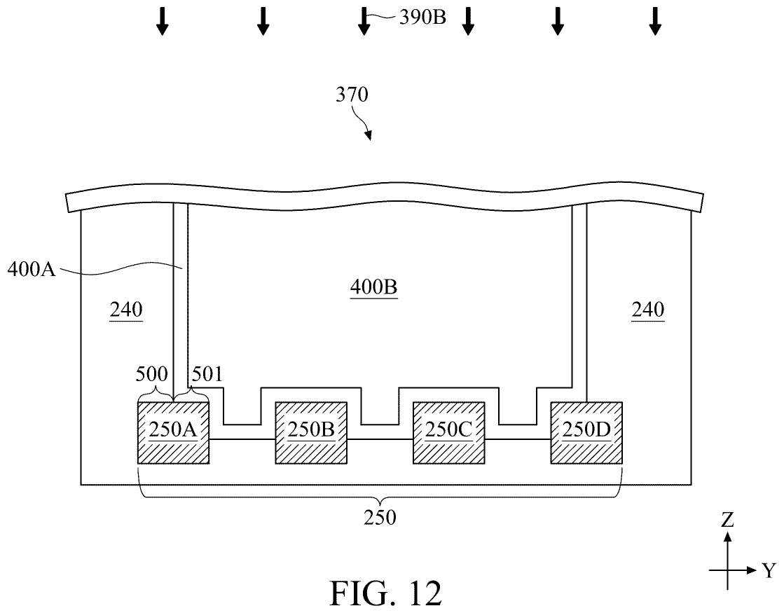

Referring now to FIG. 12, an electroplating process 390B (as a part of the TSV formation process 390) is performed to form a conductive material 400B as a rest of the TSV 400 in the recess 370. In some embodiments, the conductive material 400B includes copper, though other types of conductive material may be implemented in alternative embodiments. The conductive material 400B is formed on the barrier layer 400A. In some embodiments, the barrier layer 400A and the conductive material 400B may be formed over the upper surfaces of the dielectric material 240, and a planarization process such as a chemical mechanical polishing (CMP) process may be performed to remove the excess portions of the conductive material 400B and the barrier layer 400A formed on the upper surfaces of the dielectric material 240, so that the resulting TSV 400 and the dielectric material 240 may have substantially co-planar upper surfaces, for example, as shown in FIG. 6.

FIGS. 13A and 13B illustrate a planar top view and a cross-sectional side view, respectively, of a portion of the IC device 200 that includes the TSV 400 and the TSV landing pad 250 according to an embodiment of the present disclosure. In more detail, the planar top view of FIG. 13A corresponds to a horizontal plane defined by the X-direction and the Y-direction perpendicular to the X-direction. The cross-sectional side view of FIG. 13B corresponds to a vertical plane defined by the Y-direction and the Z-direction that is orthogonal to the horizontal X-Y plane. The cross-sectional side view of FIG. 13B is taken along a cutline A-A′ in FIG. 13A.

In the embodiment shown in FIGS. 13A-13B, the TSV landing pad 250 is implemented using five conductive segments 250A, 250B, 250C, 250D, and 250F, which are metal lines from the M_{y} interconnect layer. These conductive segments 250A-250F each extend in the X-direction horizontally and are separated from one another in the Y-direction. As such, a mesh structure is formed by the conductive segments 250A-250F. Such a mesh structure is formed to have a pattern density between about 20% and about 80%. In that regard, the pattern density of the mesh structure may be defined as the amount of area (e.g., in the top view) of the conductive segments 250A-250E divided by a total amount of area of the TSV landing pad 250, which includes the gaps (e.g., occupied by the dielectric material 240) between the conductive segments 250A-250E. In the cross-sectional side view of FIG. 13B, such a pattern density may be defined by the sum of the lateral dimensions of the conductive segments 250A-250E divided by a total lateral dimension of the TSV landing pad 250, which again includes the gaps (e.g., the gap 550 and the like) separating the conductive segments 250A-250E in the Y-direction. As discussed above, such a pattern density range is specifically configured so that the TSV landing pad 250 can achieve the potential benefits pertaining to the stress reduction and more flexible thermal contraction/expansion, while still being able to handle its intended functionality of providing electrical connectivity and mechanical support for the TSV 400.

It is also noted that, as discussed above with reference to FIGS. 10-12, the TSV 400 is formed to land on a portion, but not all, of an upper surface of some of the conductive segments 250A and 250E, which helps to minimize the formation of air bubbles or voids within the TSV 400.

FIGS. 14A and 14B illustrate a planar top view and a cross-sectional side view, respectively, of a portion of the IC device 200 that includes the TSV 400 and the TSV landing pad 250 according to another embodiment of the present disclosure. Similar to FIGS. 13A-13B, the planar top view of FIG. 14A corresponds to a horizontal plane defined by the X-direction and the Y-direction perpendicular to the X-direction. The cross-sectional side view of FIG. 14B corresponds to a vertical plane defined by the Y-direction and the Z-direction that is orthogonal to the horizontal X-Y plane. The cross-sectional side view of FIG. 14B is taken along a cutline A-A′ in FIG. 14A.

Similar to the embodiment discussed above with reference to FIGS. 13A-13B, embodiment of FIGS. 14A-14B also include the TSV landing pad 250 that is implemented using five conductive segments 250A-250F from the M_{y} interconnect layer, which form a mesh structure. Unlike the embodiment of FIGS. 13A-13B, however, the embodiment of FIGS. 14A-14B further includes an M_{y+1} interconnect layer that is located “below” the M_{y} interconnect layer in the Z-direction (e.g., located farther away from the substrate 210 than the than the M_{y} interconnect layer). In other words, the embodiment of FIGS. 14A-14B is similar to the embodiment of FIG. 9 discussed above, in that the M_{y+1} interconnect layer includes the conductive pad 470 that also has a mesh structure. The conductive pad 470 includes a plurality of conductive segments 470A-470E, which are electrically and physically coupled to the conductive segments 250A-250E, respectively, via a plurality of conductive vias 480A-480E. As discussed above with reference to FIG. 9, the conductive pad 470 may serve as an additional etching-stop layer for the etching of the recess 370 (discussed above with reference to FIG. 5). In some embodiments, the conductive pad 470 may also have a pattern density in a range between about 20% and about 80%, which is configured to reduce stress and have better thermal contraction/expansion flexibility, while still allowing the conductive pad 470 to serve as an etching-stop layer and to provide electrical connectivity and mechanical support for the TSV 400.

FIGS. 15A-15F illustrate different top views of various embodiments of the mesh structure design in a planar top view. In some embodiments, the mesh structure design shown in FIGS. 15A-15F correspond to IC design layout files, which may include a Graphic Design System (GDS) file in the format of a binary database file. Such a GDS file may specify the geometric shapes or patterns of microelectronic components, such as gates, source/drains, dielectric components, metal lines, vias, etc. In this case, the GDS file illustrates the geometric shapes or patterns of the TSV 400 and the TSV landing pad 250. In the various embodiments shown in FIGS. 15A-15F, the metal lines of the M_{y} interconnect layer are configured to form a TSV landing pad 250 that does not have a solid form, but rather one that has a mesh structure that include various gaps, holes, openings, etc., in the planar top view. One commonality among all the design of all the TSV landing pads 250 shown in FIGS. 15A-15F is that the TSV landing pads 250 each include a perimeter 600 that has a rectangular shape in the planar top view. The perimeter 600 may also be referred to as an outer ring, as it encloses or circumferentially surrounds the rest of the TSV landing pad 250 in the planar top view and may define the boundary of the TSV landing pad 250.

One reason that the perimeter 600 is implemented to have a rectangular shape in the planar top view is that such a shape may enhance the routing flexibility of the TSV landing pad 250. For example, the TSV landing pad 250 may need to be electrically connected to other IC components, and the rectangular shape of the perimeter 600 allows these electrical connections to be established more easily. For instance, the rectangular shape of the perimeter 600 may avoid potential jog issues in establishing these electrical connections. Nevertheless, it is understood that the rectangular shape of the perimeter 600 is not required unless otherwise claimed, and that the TSV landing pad 250 may have non-rectangular perimeters in other embodiments.

Referring now to FIG. 16, a process of revising an IC design layout is illustrated according to an embodiment of the present disclosure. For example, FIG. 16 illustrates the planar top views of an original IC design layout 700 and a revised IC design layout 710. In some embodiments, the original IC design layout 700 and the revised IC design layout 710 may each be in the form of a GDS file. The original IC design layout 700 may be an IC design layout generated by (or received from) an IC design house. As shown in FIG. 16, the original IC design layout 700 may include a TSV 400 and a TSV landing pad 750 that is a solid block, such as a rectangular metal block formed in the M_{y} interconnect layer. The IC design house may have generated such an IC design layout for reasons of simplicity and/or convenience, and/or without taking the issues (e.g., stress and/or wafer warpage due to thermal expansion/contraction) of such a solid block of TSV landing pad 750 into account.

According to various aspects of the present disclosure, an IC fabrication entity (e.g., a semiconductor foundry) may receive the original IC design layout 700 and modify it to generate the revised IC design layout 710. For example, the TSV landing pad 750 is modified from being a solid metal block into the TSV landing pad 250 discussed above, which has a mesh structure comprised of a plurality of conductive segments 250A-250E (e.g., as metal lines in the M_{y} interconnect layer). The TSV 400 itself may not need to be modified. As discussed above, such a mesh structure of the TSV landing pad 250 alleviates the issues pertaining to wafer warpage and/or stress. It is understood that the specific mesh structure shown in FIG. 16 is merely a non-limiting example of the revised IC design layout 710, and that other suitable mesh structures (e.g., the ones shown in FIG. 15) may be implemented for the TSV landing pad 250 as a part of the revised IC design layout in other embodiments.

FIG. 17 is a flowchart of a method 800 of fabricating an IC device according to various aspects of the present disclosure. The method 800 includes a step 810 to form a first interconnect structure over a first side of a substrate. The first interconnect structure includes a plurality of first interconnect layers embedded in a first dielectric structure. One of the first interconnect layers includes a landing pad that has a mesh structure. In some embodiments, the mesh structure is a first mesh structure, and another one of the first interconnect layers includes a second mesh structure. The second mesh structure is electrically coupled to the first mesh structure through a plurality of conductive vias of the first interconnect structure. In some embodiments, the first interconnect structure is formed such that the land pad has a rectangular boundary in a planar top view.

The method 800 includes a step 820 to form a second interconnect structure over a second side of the substrate opposite the first side. The second interconnect structure includes a plurality of second interconnect layers embedded in a second dielectric structure.

The method 800 includes a step 830 to form a recess that extends through the second dielectric structure and the substrate and partially through the first dielectric structure. The recess exposes at least a portion of the landing pad. In some embodiments, the recess is formed in a manner such that a first lateral dimension of a bottom portion of the recess is less than a second lateral dimension of a rest of the recess. In some embodiments, the landing pad includes a plurality of conductive segments in a cross-sectional side view, and the recess is formed by partially exposing upper surfaces of at least a subset of the conductive segments in the cross-sectional side view.

The method 800 includes a step 840 to form a through-substrate-via (TSV) by filling the recess with one or more conductive materials.

It is understood that the method 800 may include further steps performed before, during, or after the steps 810-840. For example, the method 800 may include a step that is performed after the forming the first interconnect structure but before the forming the second interconnect structure. Such a step may include reducing a thickness of the substrate from the second side. The second interconnect structure is formed on the second side of the substrate after the thickness of the substrate has been reduced. As another example, the method 800 may include a step that is performed after the forming the TSV. Such a step may include forming a conductive pad as a topmost one of the second interconnect layers. The conductive pad is formed to be in physical contact with the TSV from the second side. In some embodiments, the conductive pad is formed to have the mesh structure. For reasons of simplicity, other additional steps are not discussed herein in detail.

FIG. 18 illustrates an integrated circuit fabrication system 900 that can be utilized to fabricate the IC structure 200 and/or the IC chip assembly 200A according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such the processing tools to perform the various deposition processes discussed above; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

In summary, the present disclosure involves implementing a TSV landing pad that has a mesh structure, as opposed to a solid block structure. For example, such a mesh structure may include a plurality of conductive strips (e.g., as metal lines from an interconnect layer of an interconnect structure) that are separated from one another in a planar top view or in a cross-sectional side view. By implementing such a mesh structure for the TSV landing pad, the embodiments of the present disclosure offer advantages over conventional devices. It is understood, however, that other embodiments may offer additional advantages, and not all advantages are necessarily disclosed herein, and that no particular advantage is required for all embodiments. For example, the advantages may include the reduction of wafer warpage and/or stress. In that regard, a TSV landing pad in the form of a solid block may experience excessive thermal expansion and/or contraction relative to other devices, especially as IC device sizes continue to get scaled down. The excessive thermal expansion and/or contraction may lead to wafer warpage, which is undesirable. In addition, the TSV landing pad as a solid block may cause too much stress for the nearby components, which is also undesirable. The present disclosure overcomes these problems by implementing the TSV landing pad not as a solid block but as a mesh structure. Such a mesh structure offers room for the individual members of the TSV landing pad to expand or contract under different thermal conditions, which may reduce wafer warpage. In addition, such a mesh structure may reduce the amount of stress applied to nearby components, which is also beneficial. Other advantages include compatibility with existing fabrication processes and the case and low cost of implementation.

One aspect of the present disclosure pertains to an IC device. The IC device includes a substrate. The IC device includes a through-substrate-via (TSV) that extends vertically through the substrate. The IC device includes an interconnect structure disposed over a first side of the substrate. The interconnect structure includes a plurality of interconnect layers. A first interconnect layer of the plurality of interconnect layers includes a landing pad on which the TSV lands. The landing pad has a mesh structure in at least one of: a cross-sectional side view or in a planar top view.

Another aspect of the present disclosure pertains to a structure. The structure includes a substrate. The structure includes a first interconnect structure disposed over a first side of the substrate. The structure includes a second interconnect structure disposed over a second side of the substrate opposite the first side. The structure includes a through-substrate-via (TSV) that extends vertically through the substrate and at least partially through the first interconnect structure and the second interconnect structure. At least one of the first interconnect structure or the second interconnect structure includes a landing pad that physically extends to the TSV. The landing pad includes a plurality of conductive segments that are spaced apart from one another in a planar top view and in a cross-sectional side view.

Another aspect of the present disclosure pertains to a method. A first interconnect structure is formed over a first side of a substrate. The first interconnect structure includes a plurality of first interconnect layers embedded in a first dielectric structure. One of the first interconnect layers includes a landing pad that has a mesh structure. A second interconnect structure is formed over a second side of the substrate opposite the first side. The second interconnect structure includes a plurality of second interconnect layers embedded in a second dielectric structure. A recess is formed that extends through the second dielectric structure and the substrate and partially through the first dielectric structure. The recess exposes at least a portion of the landing pad. A through-substrate-via (TSV) is formed by filling the recess with one or more conductive materials.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
a substrate;
a through-substrate-via (TSV) that extends vertically through the substrate; and
an interconnect structure disposed over a first side of the substrate;
wherein:
the interconnect structure includes a plurality of interconnect layers;
a first interconnect layer of the plurality of interconnect layers includes a landing pad on which the TSV lands; and
the landing pad has a mesh structure in at least one of: a cross-sectional side view or in a planar top view.

2. The device of claim 1, wherein in the cross-sectional side view or in the planar top view, the first interconnect layer includes a plurality of conductive segments that are separated from one another by a plurality of gaps.

3. The device of claim 2, wherein in the cross-sectional side view:
a first conductive segment of the plurality of conductive segments has a planar surface that is facing toward the substrate; and
the TSV lands on a portion, but not all, of the planar surface of the first conductive segment.

4. The device of claim 1, wherein in the planar top view, a perimeter of the landing pad includes a rectangular ring.

5. The device of claim 1, wherein the first interconnect layer is disposed farther from the substrate than a rest of the interconnect layers.

6. The device of claim 1, wherein:
the plurality of interconnect layers further includes a second interconnect layer that is located farther from the substrate than the first interconnect layer;
the second interconnect layer includes a conductive pad that has the mesh structure in the cross-sectional side view or in the planar top view; and
the landing pad of the first interconnect layer and the conductive pad of the second interconnect layer are interconnected together by a plurality of conductive vias.

7. The device of claim 1, wherein:
the interconnect structure is a first interconnect structure;
the device further comprises a second interconnect structure that disposed over a second side of the substrate opposite the first side; and
the TSV extends at least partially through, and is electrically coupled to, the second interconnect structure.

8. The device of claim 7, wherein:
the second interconnect structure includes a further plurality of interconnect layers; and
the TSV is physically coupled to a second interconnect layer of the further plurality of interconnect layers.

9. The device of claim 8, wherein:
the landing pad of the first interconnect layer is a first landing pad;
the second interconnect layer includes a second landing pad that has a further mesh structure; and
the TSV is physically coupled to the second landing pad.

10. A structure, comprising:
a substrate;
a first interconnect structure disposed over a first side of the substrate;
a second interconnect structure disposed over a second side of the substrate opposite the first side; and
a through-substrate-via (TSV) that extends vertically through the substrate and at least partially through the first interconnect structure and the second interconnect structure;
wherein:
at least one of the first interconnect structure or the second interconnect structure includes a landing pad that physically extends to the TSV; and
the landing pad includes a plurality of conductive segments that are spaced apart from one another in a planar top view and in a cross-sectional side view.

11. The structure of claim 10, wherein the landing pad has a rectangular boundary in the planar top view.

12. The structure of claim 10, wherein:
the first interconnect structure and the second interconnect structure each includes a dielectric material; and
in the cross-sectional side view, an upper surface of at least one of the conductive segments of the landing pad is in direct contact with both the TSV and the dielectric material.

13. A method, comprising:
forming a first interconnect structure over a first side of a substrate, wherein the first interconnect structure includes a plurality of first interconnect layers embedded in a first dielectric structure, and wherein one of the first interconnect layers includes a landing pad that has a mesh structure;
forming a second interconnect structure over a second side of the substrate opposite the first side, wherein the second interconnect structure includes a plurality of second interconnect layers embedded in a second dielectric structure;
forming a recess that extends through the second dielectric structure and the substrate and partially through the first dielectric structure, wherein the recess exposes at least a portion of the landing pad; and
forming a through-substrate-via (TSV) by filling the recess with one or more conductive materials.

14. The method of claim 13, further comprising: after the forming the first interconnect structure but before the forming the second interconnect structure, reducing a thickness of the substrate from the second side, wherein the second interconnect structure is formed on the second side of the substrate after the thickness of the substrate has been reduced.

15. The method of claim 13, further comprising: after the forming the TSV, forming a conductive pad as a topmost one of the second interconnect layers, wherein the conductive pad is formed to be in physical contact with the TSV from the second side.

16. The method of claim 15, wherein the conductive pad is formed to have the mesh structure.

17. The method of claim 13, wherein:
the mesh structure is a first mesh structure;
another one of the first interconnect layers includes a second mesh structure; and
the second mesh structure is electrically coupled to the first mesh structure through a plurality of conductive vias of the first interconnect structure.

18. The method of claim 13, wherein the first interconnect structure is formed such that the land pad has a rectangular boundary in a planar top view.

19. The method of claim 13, wherein the recess is formed in a manner such that a first lateral dimension of a bottom portion of the recess is less than a second lateral dimension of a rest of the recess.

20. The method of claim 13, wherein:
the landing pad includes a plurality of conductive segments in a cross-sectional side view; and
the recess is formed by partially exposing upper surfaces of at least a subset of the conductive segments in the cross-sectional side view.
